(19) United States
(12) Patent Application Publication
(10) Pub. No.: US 2025/0126840 A1
(43) Pub. Date: Apr. 17, 2025

(54) SOURCE/DRAIN DIELECTRIC STRUCTURE AND MANUFACTURING METHOD THEREOF

(71) Applicant: Taiwan Semiconductor Manufacturing Company, Ltd., Hsinchu (TW)

(72) Inventors: Cheng-Yu WEI, Taoyuan City (TW); Cheng-I LIN, Hsinchu (TW); Shu-Han CHEN, Hsinchu City (TW); Chi On CHUI, Hsinchu City (TW)

(73) Assignee: Taiwan Semiconductor Manufacturing Company, Ltd., Hsinchu (TW)

(21) Appl. No.: 18/433,830

(22) Filed: Feb. 6, 2024

Related U.S. Application Data
(60) Provisional application No. 63/590,149, filed on Oct. 13, 2023.

(51) Int. Cl. H01L 29/423; H01L 21/8238; H01L 27/092; H01L 29/06; H01L 29/417; H01L 29/66; H01L 29/775; H01L 29/786

(52) U.S. Cl. CPC H10D 30/6735; H10D 30/014; H10D 30/43; H10D 30/6729; H10D 30/6757; H10D 62/121; H10D 64/021; H10D 84/0167; H10D 84/0184; H10D 84/038; H10D 84/85

(57) ABSTRACT

The present disclosure describes a semiconductor device having a source/drain dielectric. The semiconductor device includes a channel structure on a substrate, a dielectric structure on the substrate and adjacent to the channel structure, and an epitaxial structure on a top surface of the dielectric structure. The epitaxial structure is in contact with the channel structure.

### CROSS-REFERENCE TO RELATED APPLICATION

This application claims the benefit of U.S. Provisional Patent Application No. 63/590,149, titled “Semiconductor Structure and Manufacturing Method Thereof,” filed Oct. 13, 2023, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a source/drain dielectric structure, in accordance with some embodiments.

FIGS. 2A and 2B illustrate cross-sectional views of a semiconductor device having a source/drain dielectric structure, in accordance with some embodiments.

FIGS. 3A and 3B illustrates a cross-sectional view of a semiconductor device having another source/drain dielectric structure, in accordance with some embodiments.

FIG. 4 is a flow diagram of a method for fabricating a semiconductor device having a source/drain dielectric structure, in accordance with some embodiments.

FIGS. 5A-17 illustrate cross-sectional views of a semiconductor device having a source/drain dielectric structure at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, nanostructure transistors can provide improved device performance with a channel in a stacked nanosheet/nanowire configuration. The nanostructure transistors can include finFETs, gate-all-around field effect transistors (GAA FETs), nanosheet transistors, nanowire transistors, multi-bridge channel transistors, nano-ribbon transistors, and other similar structured transistors. Shallow trench isolation (STI) regions can be formed between the stacked nanosheets/nanowires for isolation. However, the substrate parasitic channel below the stacked nanosheets/nanowires can introduce leakage current and degrade device performance. Additionally, STI oxide dishing during the cleaning processes in the epitaxial growth of source/drain (S/D) structures can lead to gate collapsing defects and yield loss.

Various embodiments in the present disclosure provide methods for forming a S/D dielectric structure in a semiconductor device (e.g., a nanostructure transistor) and/or other semiconductor devices in an integrated circuit (IC). In some embodiments, a channel structure stacked on a fin structure can be formed on a substrate. A S/D dielectric structure can be formed on the fin structure and adjacent to the channel structure. An epitaxial structure can be formed on a top surface of the S/D dielectric structure. The epitaxial structure can be in contact with the channel structure. In some embodiments, the S/D dielectric structure can extend into the fin structure and a top surface of the S/D dielectric structure can be below a bottom surface of the channel structure. In some embodiments, STI regions can be formed on the substrate between the channel structure and an adjacent channel structure. The S/D dielectric structure can be formed on the STI regions. In some embodiments, a gate structure can be formed wrapping around the channel structure, a gate spacer can be formed on sidewalls of the gate structure, and a spacer dielectric structure can be formed on the gate spacer. In some embodiments, the S/D dielectric structure and the spacer dielectric structure can include the same dielectric material. In some embodiments, the S/D dielectric structure can include a first S/D dielectric layer having a first dielectric material and a second S/D dielectric layer having a second dielectric material different from the first dielectric material. In some embodiments, the S/D dielectric structure on the fin structure can reduce leakage current and improve device performance. The S/D dielectric structure on the STI regions can reduce STI oxide dishing, reduce gate collapsing defects, and improve process yield.

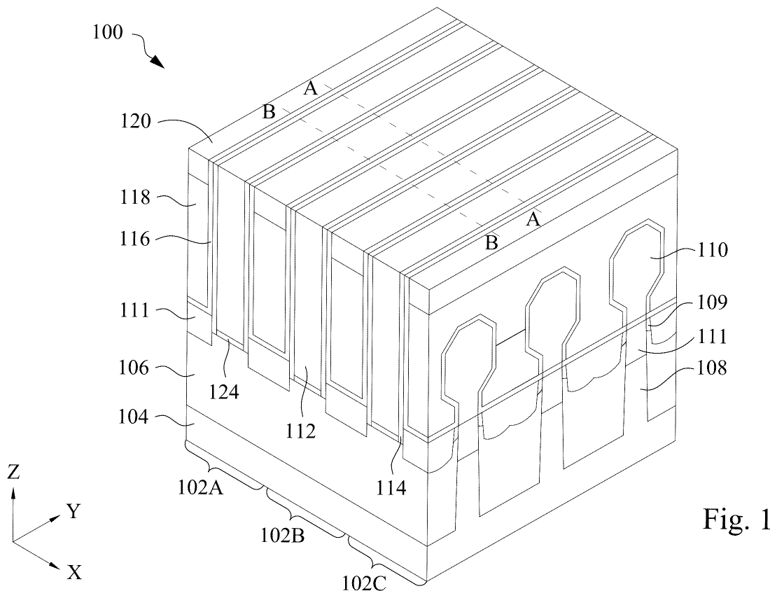

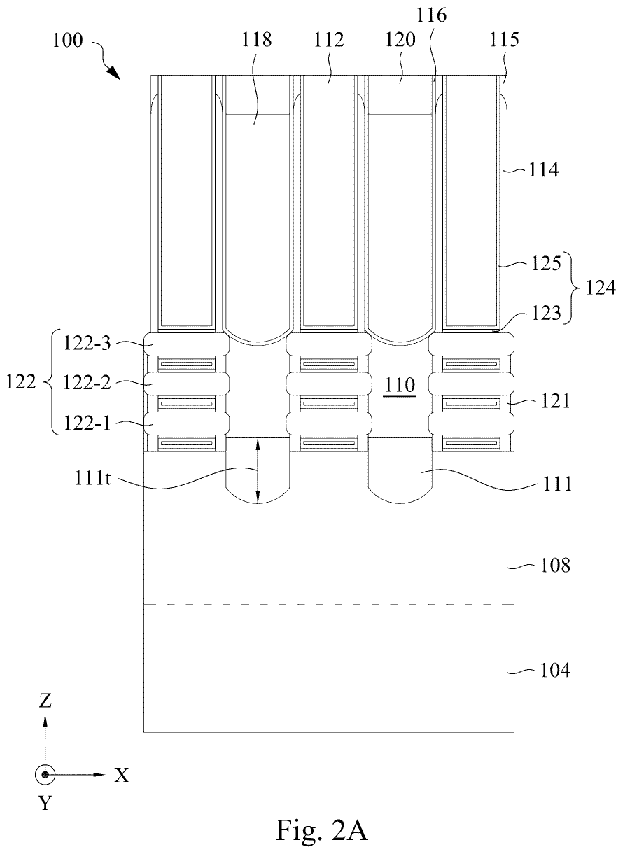

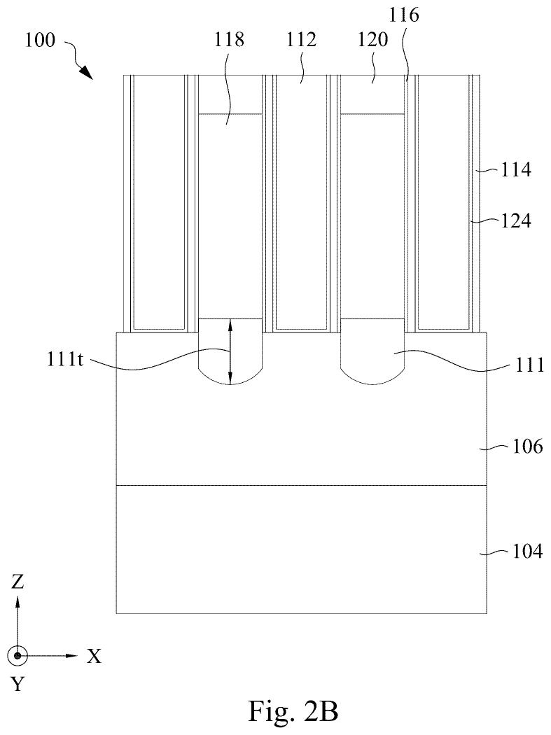

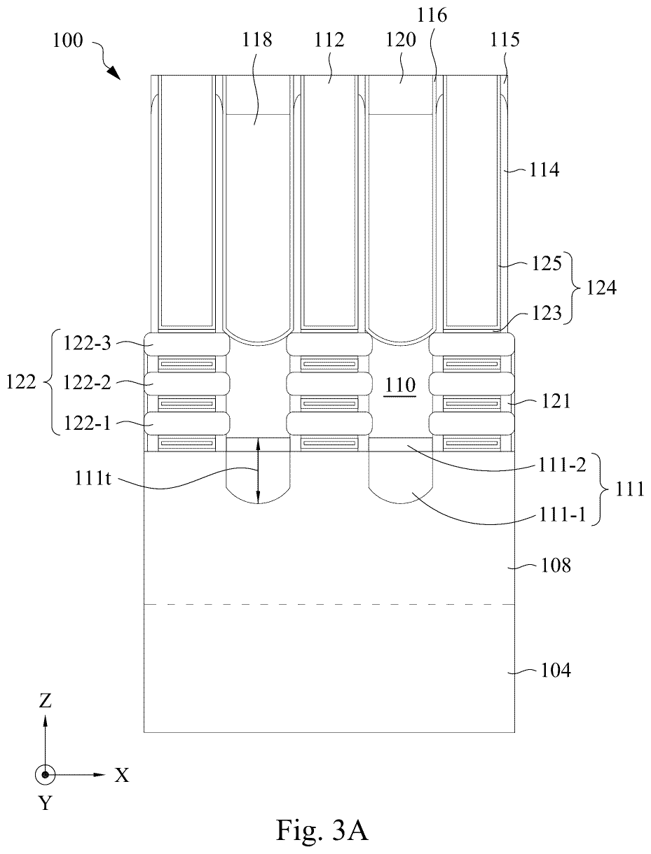

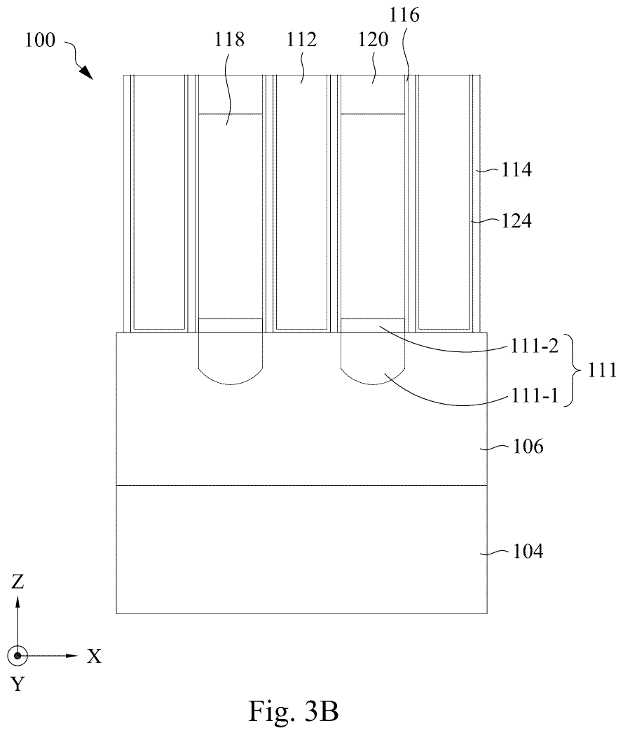

FIG. 1 illustrates an isometric view of a semiconductor device 100 having a S/D dielectric structure, in accordance with some embodiments. FIGS. 2A and 2B illustrate partial cross-sectional views of semiconductor device 100 having a S/D dielectric structure across line A-A and line B-B shown in FIG. 1, respectively, in accordance with some embodiments. FIGS. 3A and 3B illustrate partial cross-sectional views of semiconductor device 100 having another S/D dielectric structure across line A-A and line B-B shown in FIG. 1, respectively, in accordance with some embodiments.

In some embodiments, semiconductor device 100 can include transistors 102A-102C, as shown in FIG. 1. In some embodiments, transistors 102A-102C can include nanostructure transistors. The nanostructure transistors can include finFETs, GAA FETs, nanosheet transistors, nanowire transistors, multi-bridge channel transistors, nano-ribbon transistors, and other similar structured transistors. The nanostructure transistors can provide a channel in a stacked nanosheet/nanowire configuration. In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-3B, semiconductor device 100 having transistors 102A-102C can be formed on a substrate 104 and can be isolated by shallow trench isolation (STI) regions 106. Each of transistors 102A-102C can include fin structures 108, sidewall spacers 109, gate dielectric layer 124, gate structures 112, gate spacers 114, inner spacers 121, S/D dielectric structures 111, S/D structures 110, etch stop layer (ESL) 116, and interlayer dielectric (ILD) layer 118. In some embodiments, as shown in FIGS. 2A and 3A, transistors 102A-102C can have nanostructures 122-1, 122-2, and 122-3 (collectively referred to as “nanostructures 122”) on fin structures 108.

Referring to FIGS. 1-3B, substrate 104 can include a semiconductor material, such as silicon. In some embodiments, substrate 104 includes a crystalline silicon substrate (e.g., silicon wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-3B, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-3B, nanostructures 122 and fin structures 108 can extend along an X-axis for transistors 102A-102C. In some embodiments, nanostructures 122 and fin structures 108 can be disposed on substrate 104. Nanostructures 122 can include a stack of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102C. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIGS. 2A and 3A, nanostructures 122 under gate structures 112 can form channel regions of semiconductor device 100 and represent current carrying channel structures of semiconductor device 100. Though three layers of nanostructures 122 are shown in FIGS. 2A and 3A, transistors 102A-102C can have any number of nanostructures 122. In some embodiments, nanostructures 122 can have a thickness along a Z-axis ranging from about 3 nm to about 8 nm. In some embodiments, a spacing between adjacent nanostructures 122 along a Z-axis can range from about 5 nm to about 12 nm.

Referring to FIGS. 1-3B, gate dielectric layer 124 can be formed on nanostructures 122, fin structures 108, and STI regions 106. In some embodiments, gate dielectric layer 124 can be multi-layered structures and can include an interfacial layer 123 and a high-k dielectric layer 125. In some embodiments, gate dielectric layer 124 can include no interfacial layer and high-k dielectric layer 125 in direct contact with nanostructures 122. In some embodiments, interfacial layer 123 can include silicon oxide formed by a deposition process or an oxidation process. In some embodiments, interfacial layer 123 can have a thickness ranging from about 0.1 nm to about 1.5 nm. In some embodiments, high-k dielectric layer 125 can include hafnium oxide, zirconium oxide, or other suitable high-k dielectric materials.

In some embodiments, as shown in FIGS. 1-3B, gate structures 112 can be disposed on gate dielectric layer 124. In some embodiments, gate structures 112 can include one or more work function metal layers and a metal fill. The one or more work function metal layers can include work function metals to tune the threshold voltage (Vₜ) of transistors 102A-102C. In some embodiments, gate structures 112 for NFET and PFET devices can have substantially the same work-function metal. In some embodiments, gate structures 112 for NFET and PFET devices can have different work-function metals. In some embodiments, as shown in FIGS. 2A and 3A, each of nanostructures 122 can be wrapped around by gate structures 112, for which gate structures 112 can be referred to as “gate-all-around (GAA) structures” and transistors 102A-102C can also be referred to as “GAA FETs 102A-102C.” The one or more work function metal layers can wrap around nanostructures 122 and can include work function metals to tune the VI of transistors 102A-102C. In some embodiments, transistors 102A-102C can include any number of work function metal layers for VI tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1-3B, gate spacers 114 can be disposed on sidewalls of gate structures 112 and in contact with gate dielectric layer 124, according to some embodiments. Sidewall spacers 109 can be disposed on sidewalls of fin structures 108. Inner spacers 121 can be disposed adjacent to end portions of nanostructures 122 and between S/D structures 110 and gate structures 112. Gate spacers 114, sidewall spacers 109, and inner spacers 121 can include insulating materials, such as silicon oxide, silicon nitride, silicon oxynitride, silicon carbonitride, silicon oxycarbide, silicon oxycarbonitride, aluminum oxide, a low-k material, and a combination thereof. In some embodiments, gate spacers 114, sidewall spacers 109, and inner spacers 121 can include the same insulating material. In some embodiments, gate spacers 114, sidewall spacers 109, and inner spacers 121 can include different insulating materials. In some embodiments, gate spacers 114, sidewall spacers 109, and inner spacers 121 can include a single layer or a stack of insulating layers. In some embodiments, gate spacers 114, sidewall spacers 109, and inner spacers 121 can have a low-k material with a dielectric constant less than about 3.9 (e.g., about 3.5, about 3.0, or about 2.8).

In some embodiments, S/D dielectric structures 111 can be disposed on fin structures 108 and on STI regions 106. In some embodiments, S/D dielectric structures 111 can include aluminum oxide (AlOₓ), silicon carbide (SiCₓ), silicon nitride (SiNₓ), silicon carbonitride (SiCₓN₁₋ₓ), silicon oxycarbonitride (SiO_{y}CₓN_{1-x-y}), a low-k material, and a combination thereof. In some embodiments, the x in AlOₓ can range from about 0.8 to about 1.5. In some embodiments, the x in SiCₓ can range from about 0.8 to about 1. In some embodiments, the x in SiNₓ can range from about 0.8 to about 1.33. In some embodiments, the x in SiCₓN₁₋ₓ can range from about 0.5 to about 1. In some embodiments, the x in SiO_{y}CₓN_{1-x-y} can range from about 0.1 to about 0.3 and the y in SiO_{y}CₓN_{1-x-y} can range from about 0.1 to about 0.3. In some embodiments, S/D dielectric structures 111 on fin structures 108 can reduce leakage current and improve device performance. In some embodiments, S/D dielectric structures 111 on STI regions 106 can reduce STI oxide dishing adjacent to gate structures 112, reduce gate collapsing defects, and improve process yield.

In some embodiments, S/D dielectric structures 111 can have a thickness 111t along a Z-axis ranging from about 3 nm to about 7 nm. If thickness 111t is less than about 3 nm, S/D dielectric structures 111 may not reduce leakage current in semiconductor device 100 and device performance may not be improved. If thickness 111t is greater than about 7 nm, S/D dielectric structures 111 may be in contact with nanostructures 122, which can lead to reduced device current between nanostructures 122 and S/D structures 110 and degraded device performance.

In some embodiments, as shown in FIGS. 1-3B, S/D dielectric structures 111 can extend into fin structures 108 and STI regions 106. A top surface of S/D dielectric structures 111 can be above top surfaces of fin structures 108 and STI regions 106. In some embodiments, the top surface of S/D dielectric structures 111 can be below a bottom surface of bottom nanostructures 122-3 to avoid contact between S/D dielectric structures 111 and nanostructures 122. If S/D dielectric structures 111 are in contact with nanostructures 122, device current between nanostructures 122 and S/D structures 110 can be reduced and device performance can be degraded.

In some embodiments, as shown in FIGS. 3A and 3B, S/D dielectric structures 111 can include a first dielectric layer 111-1 and a second dielectric layer 111-2. First dielectric layer 111-1 can include a first dielectric material disposed on fin structures 108 and STI regions 106. Second dielectric layer 111-2 can include a second dielectric material disposed on first dielectric layer 111-1. In some embodiments, each of first and second dielectric materials can include AlOₓ, SiCₓ, SiNₓ, SiCₓN₁₋ₓ, SiO_{y}CₓN_{1-x-y}, a low-k material, or a combination thereof. In some embodiments, the first dielectric material can be different from the second dielectric material. In some embodiments, first dielectric layer 111-1 and second dielectric layer 111-2 can reduce parasitic capacitance of semiconductor device 100 and further improve device performance.

In some embodiments, as shown in FIGS. 2A and 3A, semiconductor device can further include spacer dielectric structures 115 on sidewalls of gate structures 112 and above gate spacers 114. In some embodiments, spacer dielectric structures 115 and S/D dielectric structures 111 can be formed in the same processes. In some embodiments, spacer dielectric structures 115 can include the same dielectric material as S/D dielectric structures 111. In some embodiments, spacer dielectric structures 115 can have a height along a Z-axis ranging from about 1 nm to about 5 nm.

Referring to FIGS. 1-3B, S/D structures 110 can be disposed on the top surface of S/D dielectric structures 111. S/D structures 110 can function as S/D regions of transistors 102A-102C. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. For n-type in-situ doping, n-type doping precursors, such as phosphine, arsine, and other n-type doping precursors, can be used. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. For p-type in-situ doping, p-type doping precursors, such as diborane (B₂H₆), boron trifluoride (BF₃), and other p-type doping precursors, can be used.

In some embodiments, S/D structures 110 can include one or more epitaxial layers, where each epitaxial layer can have different compositions. In some embodiments, each of the one or more epitaxial layers can include Si and differ from each other based on, for example, doping concentration and/or epitaxial growth process conditions. In some embodiments, each of the one or more epitaxial layers can include silicon germanium and differ from each other based on, for example, doping concentration, epitaxial growth process conditions, and/or relative concentration of germanium with respect to silicon.

Referring to FIGS. 1-3B, ESL 116 can be disposed on S/D structures 110, S/D dielectric structures 111 above STI regions 106, and sidewalls of gate spacers 114 and sidewall spacers 109. ESL 116 can be configured to protect S/D structures 110, S/D dielectric structures 111, and gate structures 112 during subsequent formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. In some embodiments, ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 2A-2B and 3A-3B, semiconductor device 100 can further include a protection layer 120 on ILD layer 118. In some embodiments, protection layer 120 can include a dielectric material, such as silicon nitride. In some embodiments, protection layer 120 can protect ILD layer 118 from etching damage in subsequent sheet formation process. In some embodiments, top surfaces of gate structures 112, spacer dielectric structures 115, and protection layer 120 can be coplanar.

In some embodiments, semiconductor device 100 can further include S/D contact structures, gate contact structures, metal lines, metal vias, interconnects, and additional ILD layers, which are not described in detail for clarity.

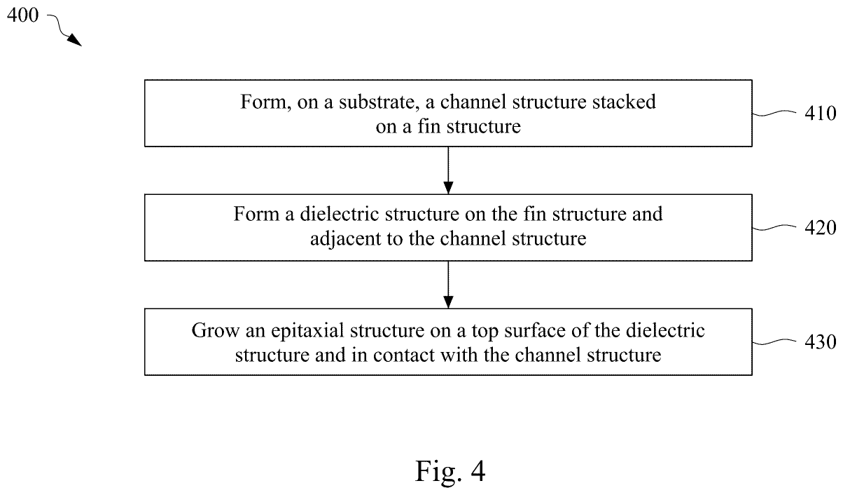

FIG. 4 is a flow diagram of a method 400 for fabricating semiconductor device 100 having a S/D dielectric structure, in accordance with some embodiments. Method 400 may not be limited to nanostructure transistor devices and can be applicable to other devices that would benefit from the S/D dielectric structure. Additional fabrication operations may be performed between various operations of method 400 and may be omitted merely for clarity and case of description. Additional processes can be provided before, during, and/or after method 400; one or more of these additional processes are briefly described herein. Moreover, not all operations may be needed to perform the disclosure provided herein. Additionally, some of the operations may be performed simultaneously or in a different order than shown in FIG. 4. In some embodiments, one or more other operations may be performed in addition to or in place of the presently-described operations.

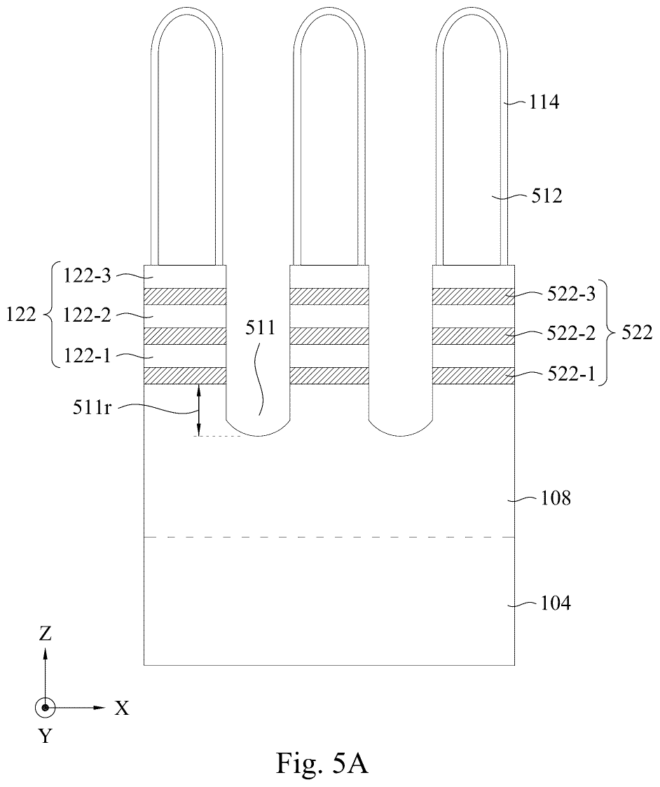

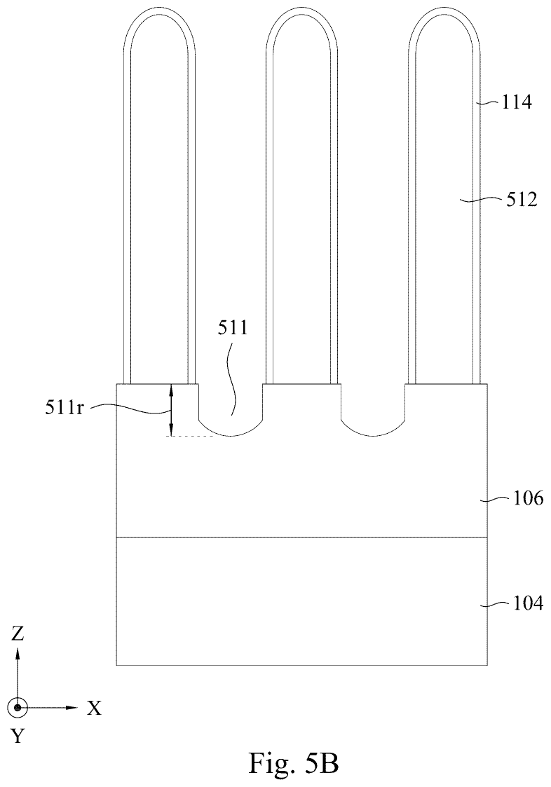

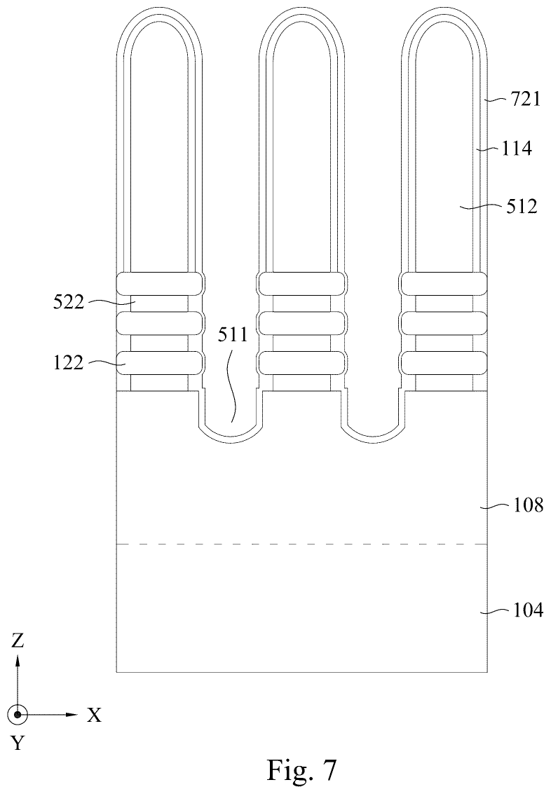

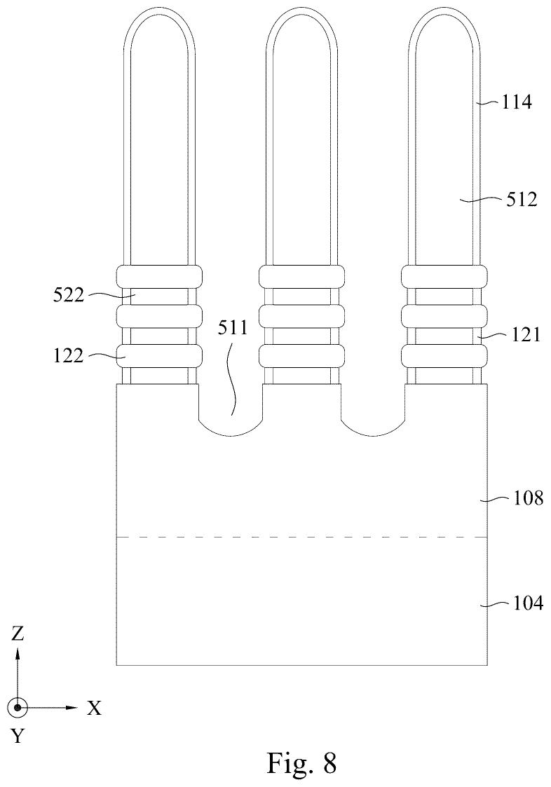

For illustrative purposes, the operations illustrated in FIG. 4 will be described with reference to the example fabrication process for fabricating semiconductor device 100 as illustrated in FIGS. 5A-17. FIGS. 5A, 6-8, 9A, 10-16A, and 17 illustrate partial cross-sectional views of semiconductor device 100 along line A-A as shown in FIG. 1 at various stages of its fabrication, in accordance with some embodiments. FIGS. 5B, 9B, and 16B illustrate partial cross-sectional views of semiconductor device 100 along line B-B as shown in FIG. 1 at various stages of its fabrication, in accordance with some embodiments. Elements in FIGS. 5A-17 with the same annotations as elements in FIGS. 1-3B are described above.

In referring to FIG. 4, method 400 begins with operation 410 and the process of forming, on a substrate, a channel structure stacked on a fin structure. For example, as shown in FIGS. 5A and 5B, nanostructures 122 and nanostructures 522-1, 522-2, and 522-3 (collectively referred to as “nanostructures 522”) stacked on fin structures 108 can be formed on substrate 104. In some embodiments, nanostructures 122 and 522 can be stacked in an alternate configuration. In some embodiments, nanostructures 122 and 522 can be epitaxially grown on substrate 104 and subsequently patterned to form nanostructures 122 and 522 stacked on fin structures 108. In some embodiments, nanostructures 122 and 522 can be in the form of nanosheets, nanowires, or nano-ribbons. In some embodiments, nanostructures 122 and 522 can include semiconductor materials similar to or different from substrate 104. In some embodiments, fin structures 108 can include the same semiconductor material as substrate 104. In some embodiments, nanostructures 122 and 522 can include different semiconductor materials. For example, nanostructures 122 can include silicon and nanostructures 522 can include silicon germanium with a germanium atomic percentage from about 10% to about 40%.

Embodiments of fin structures 108 and nanostructures 122 and 522 disclosed herein may be patterned by any suitable method. For example, the fin structures and the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures and the nanostructures.

The formation of nanostructures 122 can be followed by the formation of STI regions 106 between adjacent stacks of nanostructures 122 and 522, the formation of sacrificial gate structures 512 on nanostructures 122 and STI regions 106, the formation of gate spacers 114 on sacrificial gate structures 512, and the recess of nanostructures 122 and 522 and STI regions 106, as shown in FIGS. 5A and 5B. These processes are not described in detail for clarity. In some embodiments, after the recess of nanostructures 122 and 522, an opening 511 can be formed in nanostructures 122 and 522 and STI regions 106 between adjacent sacrificial gate structures 512. In some embodiments, opening 511 can extend into fin structures 108 and STI regions 106. In some embodiments, opening 511 can have a recess depth 511r along a Z-axis in fin structures 108 and STI regions 106 ranging from about 2 nm to about 5 nm. Recess depth 511r can ensure complete removal of bottom nanostructures 522 on fin structures 108.

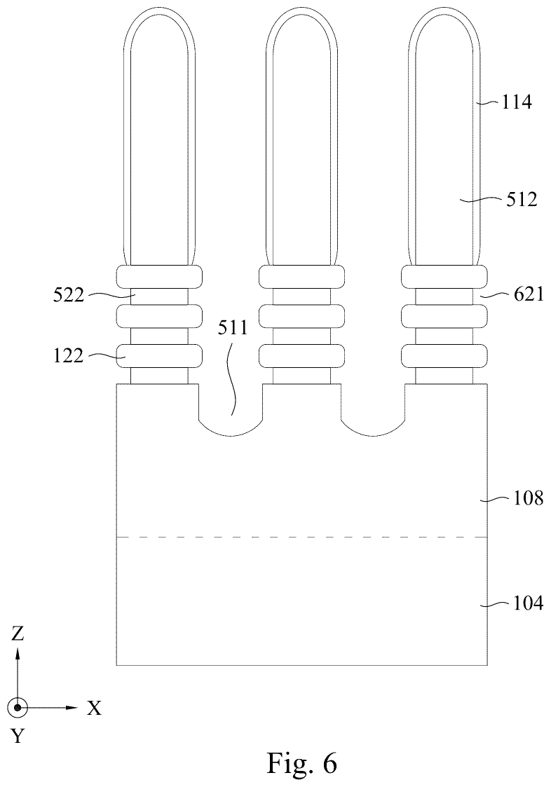

In some embodiments, the formation of opening 511 can be followed by the formation of inner spacers 121, as shown in FIGS. 6-8. In some embodiments, the formation of inner spacers 121 can include the lateral recess of nanostructures 522, the deposition of a spacer layer 721, and the trim of spacer layer 721. In some embodiments, nanostructures 522 can be laterally etched to form recesses 621 between end portions of nanostructures 122. Spacer layer 721 can be conformally deposited in recesses 621 and on gate spacers 114 and nanostructures 122. In some embodiments, spacer layer 721 can completely fill recesses 621. In some embodiments, spacer layer 721 can be directionally etched to trim spacer layer 721 on gate spacers 114 and nanostructures 122. After the directional etching process, remaining spacer layer 721 in recesses 621 can form inner spacers 121.

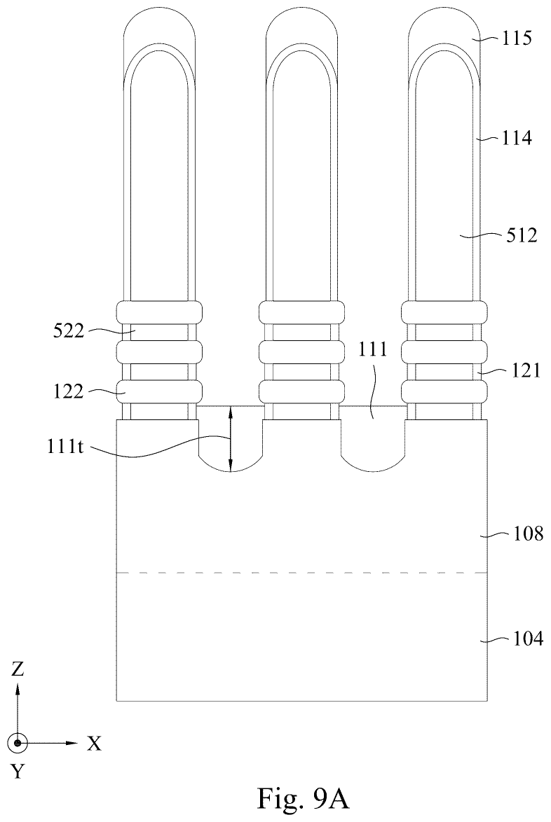

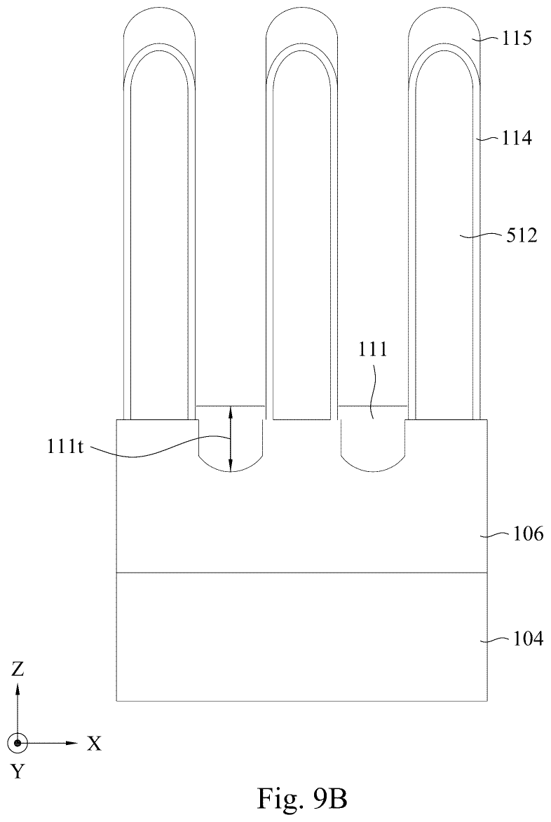

Referring to FIG. 4, in operation 420, a dielectric structure is formed on the fin structure and adjacent to the channel structure. For example, as shown in FIG. 9A, S/D dielectric structures 111 can be formed on fin structures 108 and adjacent to nanostructures 122. In some embodiments, as shown in FIG. 9B, S/D dielectric structures 111 can also be formed on STI regions 106 between adjacent sacrificial gate structures 512. In some embodiments, as shown in FIGS. 9A and 9B, spacer dielectric structures 115 can be formed on sacrificial gate structures 512. In some embodiments, a dielectric material can be directionally deposited on top surfaces of fin structures 108, STI regions 106, and gate spacers 114 to form S/D dielectric structures 111 and spacer dielectric structures 115. In some embodiments, the dielectric material may not be deposited on sidewall surfaces of gate spacers 114.

In some embodiments, the dielectric material can be deposited by plasma enhanced atomic layer deposition (PEALD) with a bias function. The PEALD can operate at a pressure from about 1 torr to about 5 torr with a precursor feed time from about 0.01 s to about 0.2 s, a purge time from about 0.5 s to about 1.5 s, and a plasma treat time from about 0.1 s to about 0.3 s. In some embodiments, the precursor feed time of the PEALD process in the diffusion mode can be less than the precursor feed time of an ALD process in the reaction mode, which can range from about 0.2 s to about 3 s. In some embodiments, the precursor treat time of the PEALD process in the diffusion mode can be less than the precursor treat time of an ALD process in the reaction mode, which can range from about 0.3 s to about 2 s. In some embodiments, the bias function and the parameter ranges of the PEALD process can facilitate directional deposition of the dielectric material on top surfaces of fin structures 108, STI regions 106, and gate spacers 114 without sidewall surface growth. In some embodiments, the dielectric material can be deposited by physical vapor deposition (PVD) at a temperature from about 350° C. to about 450° C. under a pressure from about 0.1 mtorr to about 10 mtorr. The DC plasma power of the PVD process can range from about 1 kW to about 3 KW and the processing time can range from about 2 s to about 20 s. These parameter ranges of the PVD process can facilitate directional deposition of the dielectric material on top surfaces of fin structures 108, STI regions 106, and gate spacers 114 without sidewall surface growth.

In some embodiments, S/D dielectric structures 111 and spacer dielectric structures 115 can include the same dielectric material, such as AlOₓ, SiCₓ, SiNₓ, SiCₓN₁₋ₓ, SiO_{y}CₓN_{1-x-y}, a low-k material, and a combination thereof. In some embodiments, the x in AlOₓ can range from about 0.8 to about 1.5. In some embodiments, the x in SiCₓ can range from about 0.8 to about 1. In some embodiments, the x in SiNₓ can range from about 0.8 to about 1.33. In some embodiments, the x in SiCₓN₁₋ₓ can range from about 0.5 to about 1. In some embodiments, the x in SiO_{y}CₓN_{1-x-y} can range from about 0.1 to about 0.3 and the y in SiO_{y}CₓN_{1-x-y} can range from about 0.1 to about 0.3. In some embodiments, S/D dielectric structures 111 on fin structures 108 can reduce leakage current and improve device performance. In some embodiments, S/D dielectric structures 111 on STI regions 106 can reduce STI oxide dishing adjacent to gate structures 112, reduce gate collapsing defects, and improve process yield. In some embodiments, S/D dielectric structures 111, spacer dielectric structures 115, gate spacers 114, and inner spacers 121 can include the same dielectric material. In some embodiments, S/D dielectric structures 111 and spacer dielectric structures 115 can include dielectric materials different from gate spacers 114 and/or inner spacers 121.

In some embodiments, S/D dielectric structures 111 can have a thickness 111t along a Z-axis ranging from about 3 nm to about 7 nm. If thickness 111t is less than about 3 nm, S/D dielectric structures 111 may not reduce leakage current in semiconductor device 100 and device performance may not be improved. If thickness 111t is greater than about 7 nm, S/D dielectric structures 111 may be in contact with nanostructures 122, which can lead to reduced device current between nanostructures 122 and S/D structures 110 and degraded device performance.

In some embodiments, as shown in FIGS. 9A and 9B, S/D dielectric structures 111 can extend into fin structures 108 and STI regions 106. A top surface of S/D dielectric structures 111 can be above top surfaces of fin structures 108 and STI regions 106. In some embodiments, The top surface of S/D dielectric structures 111 can be below a bottom surface of bottom nanostructures 122 to avoid contact between S/D dielectric structures 111 and nanostructures 122. If S/D dielectric structures 111 are in contact with nanostructures 122, device current between nanostructures 122 and subsequently-formed S/D structures 110 can be reduced and device performance can be degraded.

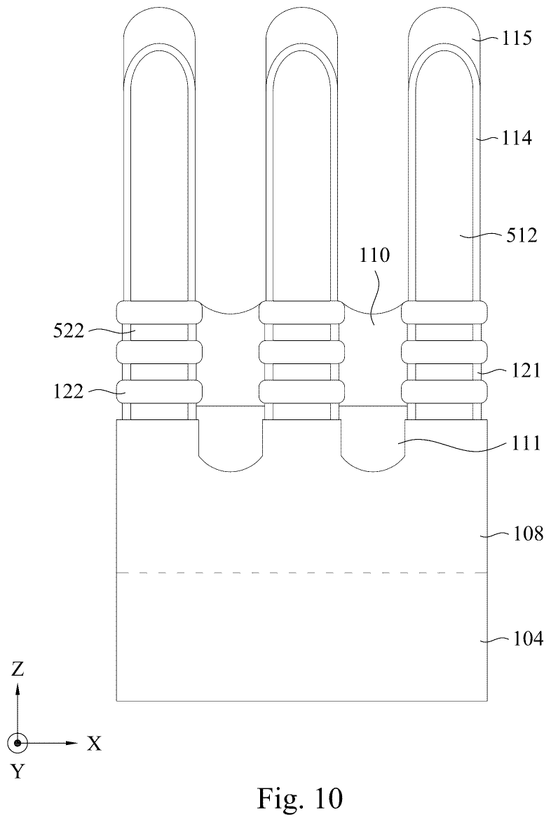

Referring to FIG. 4, in operation 430, an epitaxial structure is grown on a top surface of the dielectric structure and in contact with the channel structure. For example, as shown in FIG. 10, S/D structures 110 can be grown on a top surface of S/D dielectric structures 111 and in contact with nanostructures 122. In some embodiments, S/D structures 110 can be epitaxially grown on the top surface of S/D dielectric structures 111 and end portions of nanostructures 122. S/D structures 110 can function as S/D regions of transistors 102A-102C. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 112. In some embodiments, S/D structures 110 can include silicon and can be in-situ doped during the epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during the epitaxial growth process using p-type dopants, such as boron, indium, and gallium. In some embodiments, S/D structures 110 can include one or more epitaxial layers, where each epitaxial layer can have different compositions.

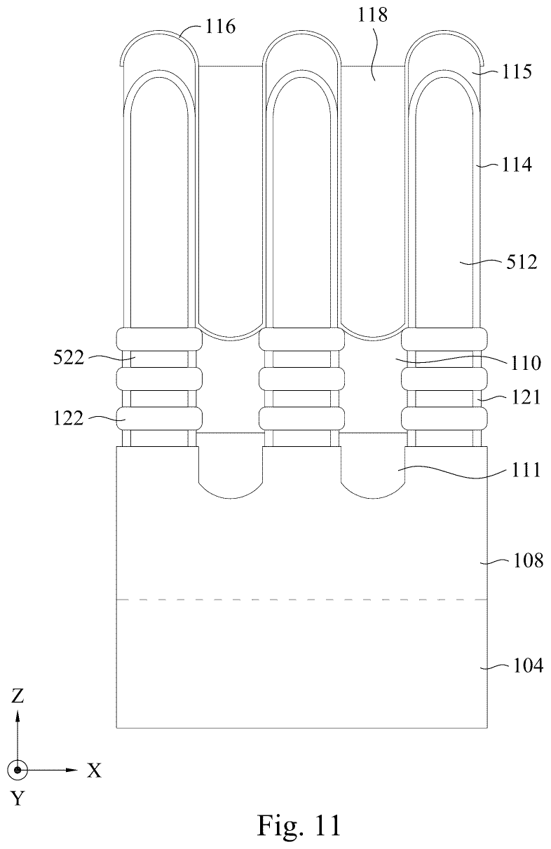

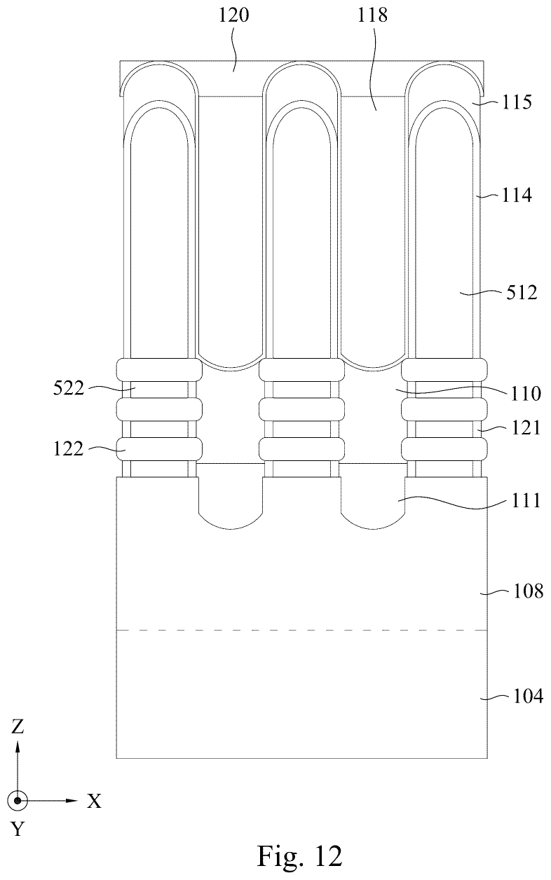

In some embodiments, the formation of S/D structures 110 can be followed by the deposition of ESL 116 and ILD layer 118, as shown in FIG. 11. ESL 116 can be conformally deposited on S/D structures 110, S/D dielectric structures 111 on STI regions 106, and sidewalls of gate spacers 114. In some embodiments, ILD layer 118 can be deposited on ESL 116 over S/D structures 110 and STI regions 106 using a deposition method suitable for flowable dielectric materials.

In some embodiments, the deposition of ESL 116 and ILD layer 118 can be followed by the formation of protection layer 120, as shown in FIG. 12. In some embodiments, a dielectric material, such as silicon nitride, can be deposited on ILD layer 118 and over sacrificial gate structures 512 followed by a chemical mechanical polishing (CMP) process. In some embodiments, protection layer 120 can protect ILD layer 118 from etching damage in subsequent sheet formation process.

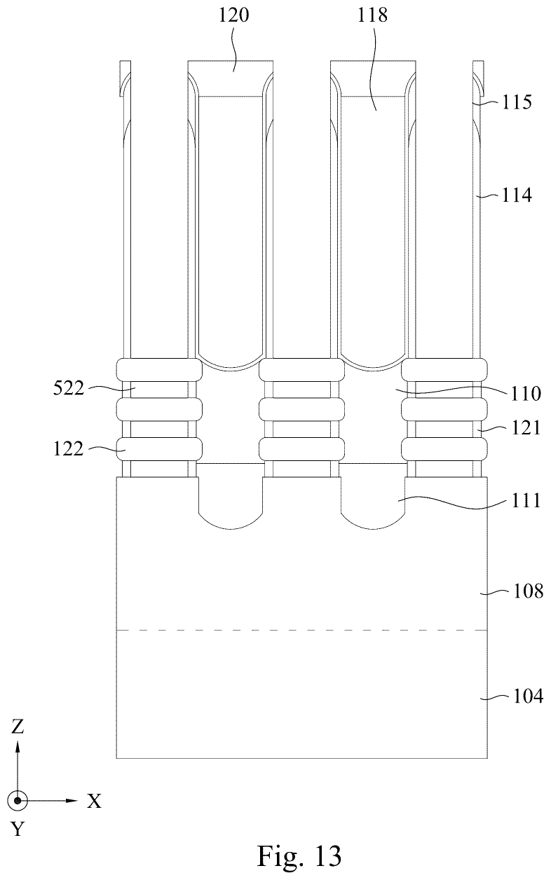

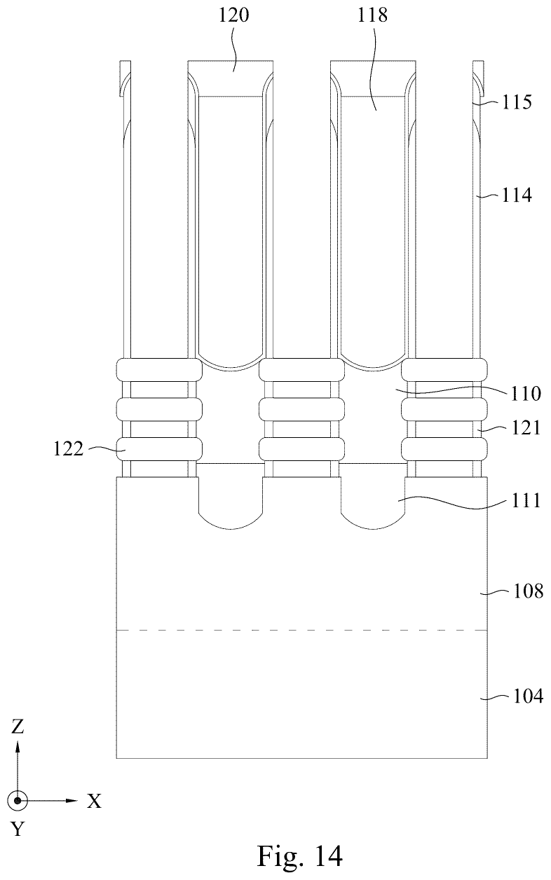

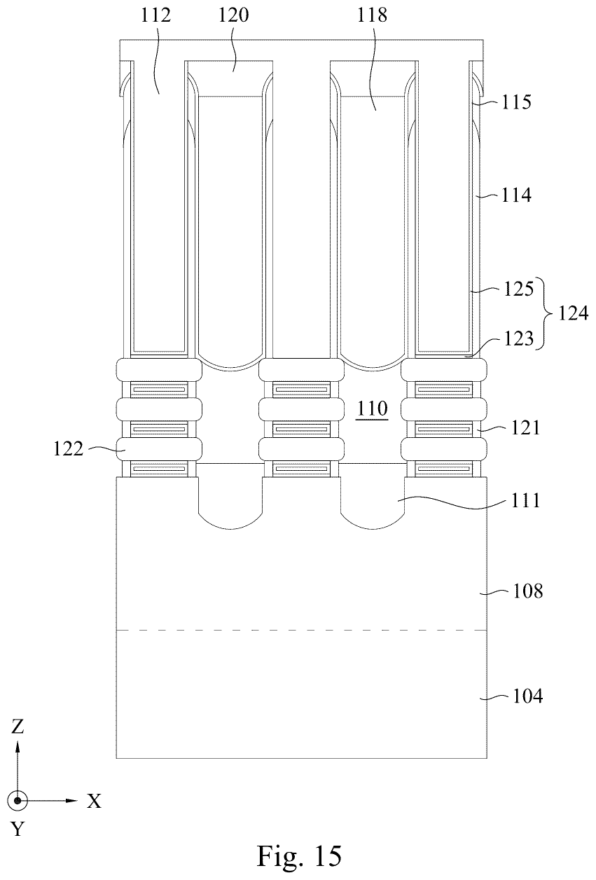

In some embodiments, the formation of protection layer 120 can be followed by replacing sacrificial gate structures 512 with metal gate structures 112, as shown in FIGS. 13-15. The replacement of sacrificial gate structures 512 can include removal of sacrificial gate structures 512, removal of nanostructures 522, and deposition of metal gate structures 112. In some embodiments, as shown in FIG. 13, a first etching process can remove sacrificial gate structures 512. In some embodiments, as shown in FIG. 14, a second etching process can remove nanostructures 522. In some embodiments, as shown in FIG. 15, interfacial layer 123 and high-k dielectric layer 125 can be formed on nanostructures 122 and sidewalls of gate spacers 114. Gate structures 112 can be deposited on nanostructures 122. In some embodiments, after deposition of gate structures 112, a CMP process can planarize top surfaces of gate structures 112, spacer dielectric structures 115, and protection layer 120, as shown in FIGS. 2A and 2B. In some embodiments, after the CMP process, spacer dielectric structures 115 can remain on gate spacers 114, as shown in FIG. 2A.

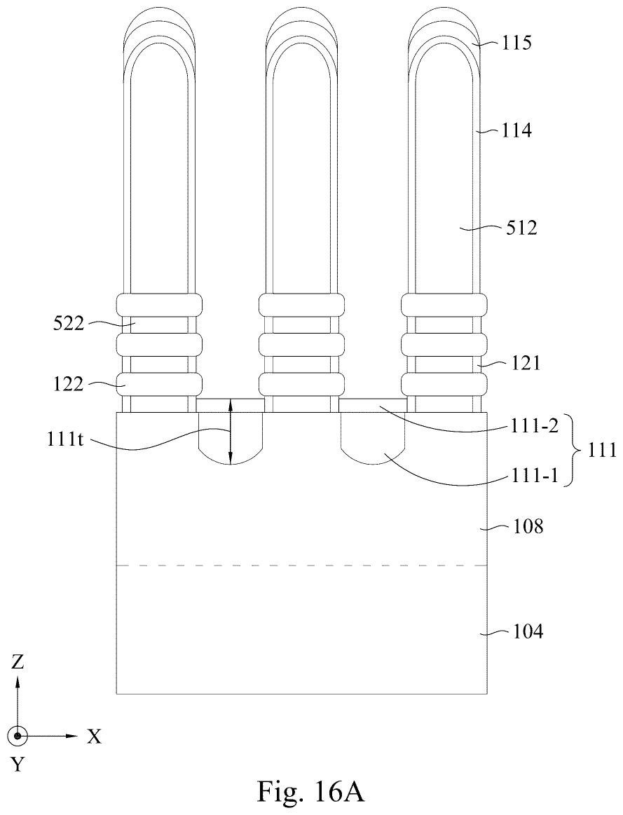

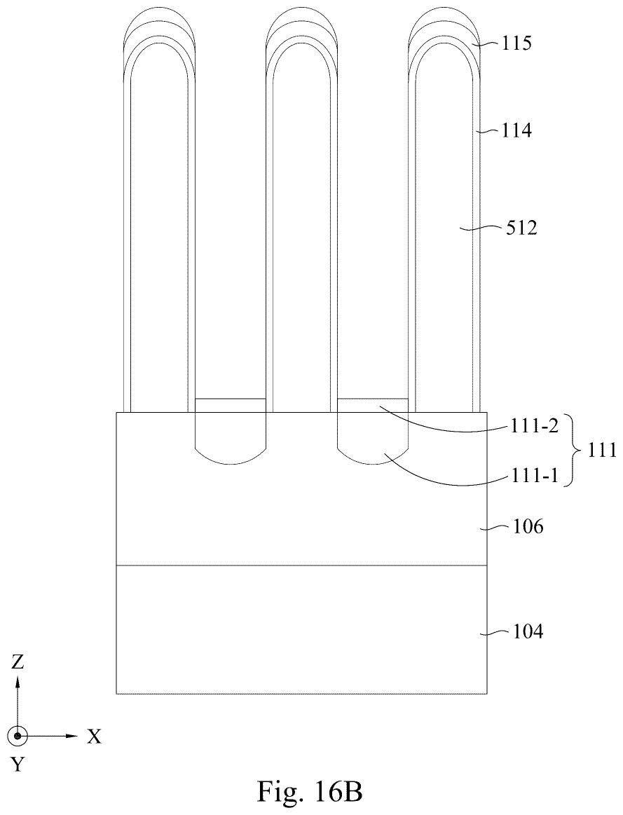

In some embodiments, in operation 420, a dielectric structure including two dielectric layers can be formed on the fin structure. For example, as shown in FIGS. 16A and 16B, first dielectric layer 111-1 can include a first dielectric material directionally deposited on fin structures 108, STI regions 106, and gate spacers 114. Second dielectric layer 111-2 can include a second dielectric material directionally deposited on first dielectric layer 111-1. In some embodiments, the first and second dielectric materials can be deposited by the same deposition method for S/D dielectric structures 111 as described above, such as the PEALD process and the PVD process. In some embodiments, each of the first and second dielectric materials can include AlOₓ, SiCₓ, SiNₓ, SiCₓN₁₋ₓ, SiO_{y}CₓN_{1-x-y}, a low-k material, or a combination thereof. In some embodiments, the first dielectric material can be different from the second dielectric material. In some embodiments, first and second dielectric layers 111-1 and 111-2 on fin structures 108 can reduce leakage current and improve device performance. In some embodiments, first and second dielectric layers 111-1 and 111-2 on STI regions 106 can reduce STI oxide dishing adjacent to gate structures 112, reduce gate collapsing defects, and improve process yield.

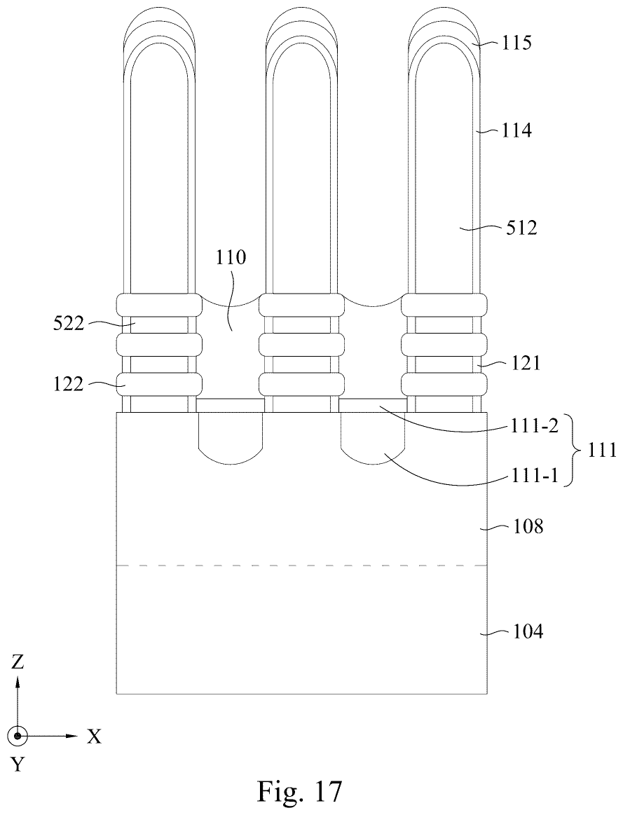

In some embodiments, the deposition of first dielectric layer 111-1 and second dielectric layer 111-2 can be followed by the formation of S/D structures 110 on second dielectric layer 111-2, as shown in FIG. 17. In some embodiments, S/D structures 110 can be epitaxially grown on second dielectric layer 111-2 as described above in operation 430. In some embodiments, the formation of S/D structures 110 can be followed by the deposition of ESL 116 and ILD layer 118, the formation of protection layer 120, and the formation of gate structures 112, which are described in detail above. After the formation of gate structures 112, a CMP process can planarize top surfaces of gate structures 112, spacer dielectric structures 115, and protection layer 120, as shown in FIGS. 3A and 3B. In some embodiments, first and second dielectric layers 111-1 and 111-2 can reduce parasitic capacitance of semiconductor device 100 and further improve device performance.

Various embodiments in the present disclosure provide example methods for forming S/D dielectric structures 111 in semiconductor device 100. In some embodiments, nanostructures 122 stacked on fin structures 108 can be formed on substrate 104. S/D dielectric structures 111 can be formed on fin structures 108 and adjacent to nanostructures 122. S/D structures 110 can be formed on a top surface of S/D dielectric structures 111. S/D structures 110 can be in contact with nanostructures 122. In some embodiments, S/D dielectric structures 111 can extend into fin structures 108 and a top surface of S/D dielectric structures 111 can be below a bottom surface of nanostructures 122. In some embodiments, STI regions 106 can be formed on substrate 104 between nanostructures 122. S/D dielectric structures 111 can be formed on STI regions 106. In some embodiments, gate structures 112 can be formed wrapping around nanostructures 122, gate spacers 114 can be formed on sidewalls of gate structures 112, and spacer dielectric structures 115 can be formed on gate spacers 114. In some embodiments, S/D dielectric structures 111 and spacer dielectric structures 115 can include the same dielectric material. In some embodiments, S/D dielectric structures 111 can include first S/D dielectric layer 111-1 having a first dielectric material and second S/D dielectric layer 111-2 having a second dielectric material different from the first dielectric material. In some embodiments, S/D dielectric structures 111 on fin structures 108 can reduce leakage current and improve device performance. S/D dielectric structures 111 on STI regions 106 can reduce STI oxide dishing, reduce gate collapsing defects, and improve process yield.

In some embodiments, a semiconductor structure includes a channel structure on a substrate, a gate structure wrapped around the channel structure, an inner spacer adjacent to end portions of the gate structure and the channel structure, a dielectric structure on the substrate and adjacent to the channel structure, and an epitaxial structure on a top surface of the dielectric structure. The dielectric structure is in contact with the inner spacer. The epitaxial structure is in contact with the channel structure.

In some embodiments, a semiconductor device includes first and second channel structures on a fin structure, a dielectric structure on the fin structure and between the first and second channel structures, and a source/drain (S/D) structure on a top surface of the dielectric structure. The dielectric structure extends into the fin structure. The S/D structure is in contact with the first and second channel structures and the dielectric structure is below the first and second channel structures.

In some embodiments, a method includes forming, on a substrate, a channel structure stacked on a fin structure, forming a gate structure on the channel structure, forming a recess in the fin structure adjacent to the channel structure and the gate structure, depositing a dielectric material in the recess to form a dielectric structure on the fin structure, and growing an epitaxial structure on a top surface of the dielectric structure. The epitaxial structure is in contact with the channel structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel structure on a substrate;
a gate structure wrapped around the channel structure;
an inner spacer adjacent to end portions of the gate structure and the channel structure;
a dielectric structure on the substrate and adjacent to the channel structure, wherein the dielectric structure is in contact with the inner spacer; and
an epitaxial structure on a top surface of the dielectric structure, wherein the epitaxial structure is in contact with the channel structure.

2. The semiconductor structure of claim 1, wherein a top surface of the dielectric structure is below a bottom surface of the channel structure.

3. The semiconductor structure of claim 1, wherein a thickness of the dielectric structure ranges from about 3 nm to about 7 nm.

4. The semiconductor structure of claim 1, further comprising:
a gate spacer on a sidewall of the gate structure; and
an additional dielectric structure on the sidewall of the gate structure and above the gate spacer, wherein the dielectric structure and the additional dielectric structure comprise a same dielectric material.

5. The semiconductor structure of claim 4, wherein the dielectric structure and the additional dielectric structure comprise a same dielectric material.

6. The semiconductor structure of claim 4, further comprising an interlayer dielectric (ILD) layer on the epitaxial structure and a protection layer on the ILD layer, wherein top surfaces of the protection layer and the additional dielectric structure are coplanar.

7. The semiconductor structure of claim 4, wherein top surfaces of the gate structure and the additional dielectric structure are coplanar.

8. The semiconductor structure of claim 1, wherein the dielectric structure comprises aluminum oxide, silicon carbide, silicon carbonitride, silicon nitride, silicon oxycarbonitride, or a low-k dielectric material.

9. The semiconductor structure of claim 1, wherein the dielectric structure comprises a first dielectric layer with a first dielectric material and a second dielectric layer with a second dielectric material different from the first dielectric material.

10. A semiconductor device, comprising:
first and second channel structures stacked on a fin structure;
a dielectric structure on the fin structure and between the first and second channel structures, wherein the dielectric structure extends into the fin structure and the dielectric structure is below the first and second channel structures; and
a source/drain (S/D) structure on a top surface of the dielectric structure, wherein the S/D structure is in contact with the first and second channel structures.

11. The semiconductor device of claim 10, wherein a top surface of the dielectric structure is below bottom surfaces of the first and second channel structures.

12. The semiconductor device of claim 10, wherein a thickness of the dielectric structure ranges from about 3 nm to about 7 nm.

13. The semiconductor device of claim 10, further comprising:
a gate structure wrapped around the first channel structure;
a gate spacer on a sidewall of the gate structure; and
an additional dielectric structure on the sidewall of the gate structure and above the gate spacer.

14. The semiconductor device of claim 13, wherein the dielectric structure and the additional dielectric structure comprise a same dielectric material.

15. The semiconductor device of claim 13, further comprising an inter-layer dielectric (ILD) layer on the epitaxial structure and a protection layer on the ILD layer, wherein top surfaces of the protection layer and the additional dielectric structure are coplanar.

16. The semiconductor device of claim 10, wherein the dielectric structure comprises a first dielectric layer with a first dielectric material and a second dielectric layer with a second dielectric material different from the first dielectric material.

17. A method, comprising:
forming, on a substrate, a channel structure stacked on a fin structure;
forming a gate structure on the channel structure;
forming a recess in the fin structure adjacent to the channel structure and the gate structure;
depositing a dielectric material in the recess to form a dielectric structure on the fin structure; and
growing an epitaxial structure on a top surface of the dielectric structure, wherein the epitaxial structure is in contact with the channel structure.

18. The method of claim 17, wherein depositing the dielectric material comprises directionally depositing a dielectric material on the gate structure and the fin structure.

19. The method of claim 17, further comprising:
forming a gate spacer on sidewalls of the gate structure;
depositing the dielectric material on the gate spacer; and
removing a portion of the dielectric material to form an additional dielectric structure on the gate spacer.

20. The method of claim 19, further comprising:
forming an inter-layer dielectric (ILD) layer on the epitaxial structure;
forming a protection layer on the ILD layer; and
planarizing top surfaces of the protection layer, the additional dielectric structure, and the gate structure.
